(19) United States
(12) Patent Application Publication
(10) Pub. No.: US 2007/0133177 A1
(43) Pub. Date: Jun. 14, 2007

(54) FLEXING CHIP HEATSINK

(75) Inventors: Beth Frayne Loebach, Raleigh, NC (US); Adam Ian Armstrong, Durham, NC (US); Dale W. Wilhite, Apex, NC (US)

Correspondence Address: GERALD J. IWANEJKO, JR., 229 HICKORY HILL DRIVE, VOLANT, PA, 16156, US

(73) Assignee: INTERNATIONAL BUSINESS MACHINES CORPORATION, Armonk, NY (US)

(21) Appl. No.: 11/306,037

(22) Filed: Dec. 14, 2005

(51) Int. Cl. H05K 7/20

(52) U.S. Cl. 361/704

(57) ABSTRACT

A method, apparatus and system are disclosed for using a flexible radiating heatsink for cooling electronic components on integrated circuit chips. The heatsink elastically deforms without breaking or disconnecting in response to an external contact and then returns to its original size, shape and position, without transmitting the external force to the electronic component(s) it is cooling.

### TECHNICAL FIELD

This invention relates to heat dissipators (or “heatsinks”) used for cooling electronic components, and in particular to a heat dissipator used with integrated circuits (“ICs”). More particularly, this invention relates to the field of radiating heatsinks, and specifically to a flexible metal radiating heatsink for cooling electronic components on IC chips, that elastically deforms without breaking or disconnecting in response to an external contact and then returns to its original size, shape and position, without transmitting the external force to the electronic component(s) it is cooling.

### BACKGROUND

Miniaturization of electronic devices is made possible today largely through the use of integrated circuits (“ICs”), in which a large number of electronic components such as various types of transistors, capacitors, resistors, amplifiers, logic circuits and others are manufactured, located, and electrically connected and combined together into circuits on a small monolithic integrated circuit (“IC”) chip (or “microchip”). The high concentration of electronic components on an IC chip necessarily confines the electrical power consumption of these components to a small area. This power consumption results in the generation of a substantial amount of thermal heat, which must be removed or dissipated away from the circuits on the IC chip during operation. In the case of many electronic devices such as computer processors, memory modules, sensors, transmitters, receivers, converters, regulators and others (which are all now being manufactured in IC form) the heat generated by these devices must be dissipated rapidly and efficiently to prevent their abnormal operation and possible destruction due to overheating. This has led to the use of heat dissipators (or “heatsinks”) in conjunction with integrated circuits, which transfer heat energy away from the IC during operation by thermal conduction from the IC to the heatsink through direct contact, and subsequent radiation of the heat into the surrounding air for removal by natural or forced convection.

As electronic and computer technology advances to sub-micron age, the physical dimension of IC microchips dramatically shrinks, and the number and density of installed electronic components (along with their operating speed) greatly increases. This causes an increase in generated heat during operation, and metal radiating heatsink “fins” having a large heat dissipating surface area are typically combined with the microchips to remove this heat. Generally, there are three types of heatsinks used (“aluminum extrusion”, “press molded”, and “folded stack”) which are characterized by their fabrication method. However, the aluminum extrusion and press molded types are being increasingly replaced by folded stack radiating heatsink fins, which can be fabricated for use with higher density ICs to provide satisfactory cooling within a limited physical area or volume.

### SUMMARY OF THE INVENTION

In order for folded stack radiating heatsink fins to provide satisfactory cooling performance when used with high density IC microchips, they must be manufactured to contact the IC chip within a limited area (or “small footprint”) to save space, which in turn requires them to possess an extended (or “tall”) vertical dimension to provide enough surface area exposed to a sufficient volume of ambient air for satisfactory heat dissipation to occur. However, even though such a “small footprint”/“tall” heatsink configuration provides adequate cooling for high density IC microchips, its extended height causes problems (particularly during manufacturing) by increasing the tendency of the heatsink to “break off” (or disconnect) from its IC and printed circuit board (PCB) in response to accidental contact, due to the increased rotational moment created by its extended vertical profile.

The present invention solves this problem by providing a flexible radiating heatsink that will elastically deform without breaking or disconnecting from its IC chip in response to an external contact, and then return to its original size, shape and position without transmitting the external force to the electronic component(s) it is cooling. This is accomplished by using an array of connected flexible joints providing a “folded configuration” instead of a rigid extrusion for the heatsink skeletal construction. Metals or other materials having a high thermal heat conductivity (such as for example copper or aluminum) are preferably constructed into flexible corrugated thin sheets which are connected together to form a “small footprint”/“tall” heatsink configuration. Use of such a configuration allows the heatsink structure to absorb stress by resiliently flexing and then returning to its original shape without breaking in reaction to a contact, instead of transmitting the contact force to the connection between the heatsink and its IC/PCB and breaking off in response to a shearing stress.

It is therefore an object of the present invention to overcome the disadvantages of the prior art by providing a method, apparatus and system using a flexible radiating heatsink for cooling electronic components on integrated circuit chips that is constructed with an array of connected flexible joints which elastically deform without breaking or disconnecting from the chip in response to an external contact force and then return to an original size, shape and position without transmitting the external force to the cooled component(s).

It is another object of the present invention to overcome the disadvantages of the prior art by providing a flexible radiating heatsink that is constructed of material(s) capable of assuming a configuration having sufficient flexibility to remain within plastic limits during elastic deformation so as to resiliently absorb stress instead of breaking in reaction to a contact force or transmitting the force to the cooled electronic component(s).

It is another object of the present invention to overcome the disadvantages of the prior art by providing a flexible radiating heatsink that is constructed with corrugated thin metal sheets joined together into an array configuration having a limited area in contact with the cooled component(s) and an extended dimension providing a sufficient surface area exposed to ambient air to allow adequate heat dissipation to occur.

It is another object of the present invention to overcome the disadvantages of the prior art by providing a flexible radiating heatsink that is constructed of material(s) having a high thermal conductivity for cooling electronic components on high density integrated circuit chips.

The subject matter which is regarded as the invention is particularly pointed out and distinctly claimed in the concluding portion of the specification. The invention, however, together with further objects and advantages thereof, may best be understood by reference to the following description taken in conjunction with the accompanying drawings.

### BRIEF DESCRIPTION OF THE DETAILED DRAWINGS

FIG. 1 is a perspective view of a flexible radiating heatsink of the present invention combined with a substrate.

FIG. 2 is a perspective view of a flexible radiating heatsink of the present invention when flexing in response to an external contact.

FIG. 3 is an exploded view of a prior art heatsink in operative engagement with an integrated circuit (IC) and a printed circuit board (PCB).

FIG. 4 is a perspective view of the prior art heatsink of FIG. 3 in operative engagement with an integrated circuit (IC).

FIG. 5 is a perspective view of a prior art folded stack radiating heatsink fin combined with a substrate.

### DETAILED DESCRIPTION OF THE PREFERRED EMBODIMENTS

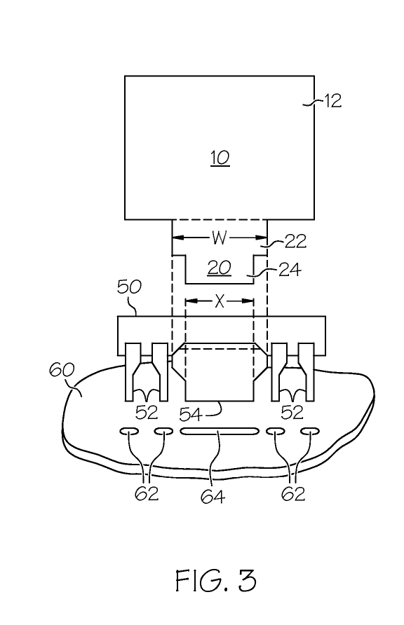

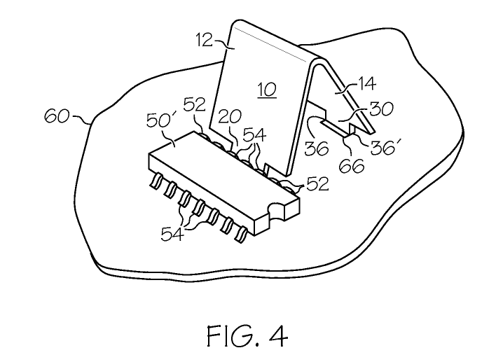

Integrated circuits (ICs) may be produced in a variety of packages. A common one is the dual-in-line package (or DIP) as shown in the prior art configurations of FIG. 3 & FIG. 4, in which the IC chip 50 is encased in a rectangular box of dielectric material. Numerous metallic terminals or pins 52 are located along sides of the DIP package. Several of the pins 52 are connected to the IC chip 50 inside the box, thereby permitting electrical connections to be made to the circuit(s) located on the chip. Other pins 54 (usually those closest to the centrally located chip) are in physical contact with the metallic ground plane on the bottom of the chip 50 and are used to conduct heat from the chip to the external environment. A heat dissipator (or “heatsink”) 10 may be attached so as to contact the heat-conducting pins 54 and thereby conduct heat away from the IC chip 50. The heatsink 10 is usually attached prior to mounting the IC chip 50 in a printed circuit board (PCB) (not shown) by fixedly attaching the IC pins 52 & 54 to the PCB such as by soldering.

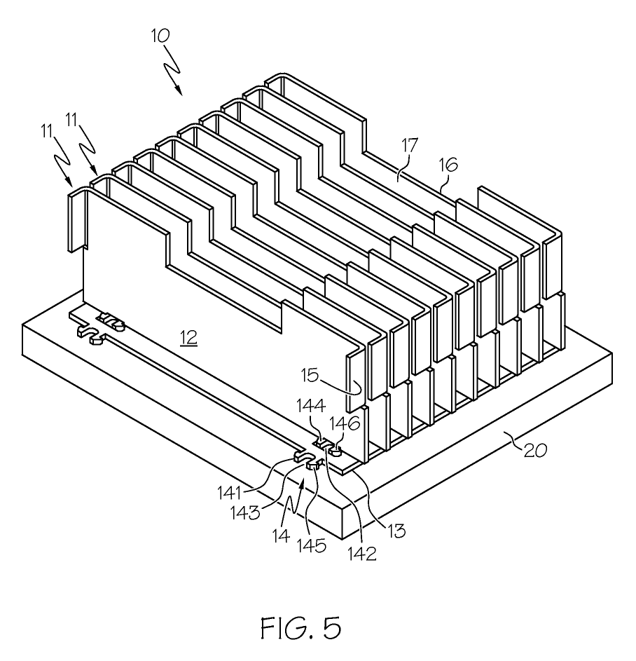

FIG. 5 illustrates a typical view of a prior art folded stack radiating heatsink fin structure 10, comprising a plurality of metal plates 11 of similar size, each formed by a conventional mechanical pressing, molding or extrusion method. Each metal plate 11 has a main body 12 connected with a folded side portion 13 containing a protrusion 14 and a recess 142 that can be used to position adjacent plates 11 (by engagement of the protrusion of one plate with the corresponding recess of an adjacent plate) so as to form a solid “fin-type” stack, as described for example in U.S. Pat. No. 6,672,379 which is incorporated by reference herein. The metal plates 11 are connected with a heat conducting IC substrate 20 by such known methods as gluing or soldering their sides 13 to the surface of the substrate 20. The heatsink 10 and substrate 20 combination is then attached to an IC chip 50 to dissipate the heat it generates.

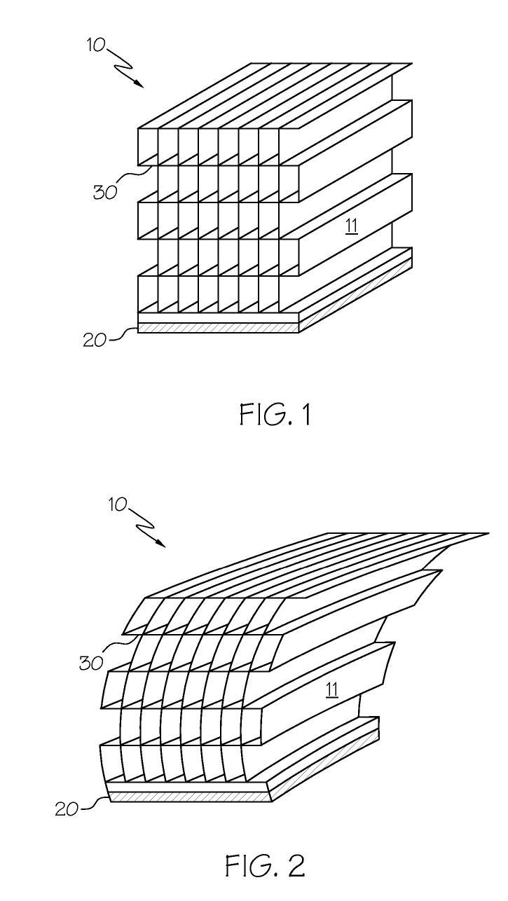

Referring to FIG. 1 & FIG. 2, the present invention is directed to a flexible radiating heatsink that is especially suited for electronic heat generating devices such as IC microchips. As with the prior art embodiment shown in FIG. 5, heatsink 10 is preferably comprised of a plurality of thin sheet metal plates 11, each of which is cut into similar size and shape and formed by a conventional method. The heatsink 10 is provided with a high efficiency heat dissipating area since its metal plates 11 are typically made of materials with high thermal heat conductivity such as copper, aluminum and/or materials of similar thermal conductivity and mechanical flexibility. The number, size and shape of the metal plates 11 is subject to change depending upon the type of IC chip 50 for which heatsink 10 is to be used (and the amount of heat to be dissipated). The substrate 20 is also typically made of materials that have high thermal conductivity.

As shown in FIG. 1, heatsink 10 is configured to contact the IC chip substrate 20 within a limited surface area (or “small footprint”) to save space, and it possesses an extended (or “tall”) vertical height dimension in order to provide a surface area that is sufficiently exposed to ambient air for adequate heat dissipation to occur. However, this “tall” height increases the tendency of the heatsink to “break off” (or disconnect) from its IC chip and printed circuit board (PCB) in response to accidental contact during manufacturing (or otherwise), due to the increased rotational moment created by its extended vertical profile.

To solve this problem, each of the metal plates 11 are preferably formed into a corrugated “fin” shape and are then connected together using an array of flexible joints 30 to provide a “folded configuration” for the skeletal construction of the heatsink 10. As shown in FIG. 2, the use of corrugation instead of a rigid extrusion adds flexibility to the heat sink fins 11 (thus increasing resistance to external contact) and it causes the metal material to remain within plastic limits during deformation, allowing the heatsink 10 to absorb shock and return back to its original form, instead of transmitting the contact force to the connection between the heatsink 10 and substrate 20 causing it to break off in response to shear stress.

The present invention thus overcomes the disadvantages of the prior art by providing a flexible metal radiating heatsink for cooling electronic components on IC chips that elastically deforms without breaking or disconnecting in response to an external contact, and then returns to its original size, shape and position without transmitting the external force to the electronic component(s) it is cooling.

While certain preferred features of the invention have been shown by way of illustration, many modifications and changes can be made that fall within the true spirit of the invention as embodied in the following claims, which are to be interpreted as broadly as the law permits to cover the full scope of the invention, including all equivalents thereto.

1. A flexible radiating heatsink for cooling at least one electronic component on an integrated circuit chip, comprised of one or more thermally conductive materials configured in an array of connected flexible joints that elastically deform without breaking or disconnecting from the chip in response to an external contact force and then return to an original size, shape and position without transmitting the external force to the cooled component(s),
wherein the array of flexible joints is comprised of a plurality of corrugated thin metal sheets joined together into a foldable skeletal construction having a limited area in contact with the cooled component(s) and an extended dimension providing at least one surface area exposed to ambient air for heat dissipation.

2. A flexible radiating heatsink of claim 1 wherein the array assumes a configuration having sufficient flexibility to remain within plastic limits during deformation so as to resiliently absorb stress.

3. (canceled)

4. A flexible radiating heatsink of claim 1 comprised of at least one material having a high thermal conductivity for cooling one or more electronic components on a high density integrated circuit chip.

5. A flexible radiating heatsink of claim 4 wherein at least one material is comprised of a metal selected from the group consisting of copper, aluminum or materials of similar thermal conductivity and mechanical flexibility.

6. A computer system comprised of one or more integrated circuit chips and including at least one flexible radiating heatsink for cooling one or more electronic components on a chip, wherein the heatsink is comprised of one or more thermally conductive materials configured in an array of connected flexible joints that elastically deform without breaking or disconnecting from the chip in response to an external contact force and then return to an original size, shape and position without transmitting the external force to the cooled component(s),
wherein the array of flexible joints is comprised of a plurality of corrugated thin metal sheets joined together into a foldable skeletal construction having a limited area in contact with the cooled component(s) and an extended dimension providing at least one surface area exposed to ambient air for heat dissipation.

7. The computer system of claim 6 wherein the heatsink array assumes a configuration having sufficient flexibility to remain within plastic limits during deformation so as to resiliently absorb stress.

8. (canceled)

9. The computer system of claim 6 wherein one or more heatsinks are comprised of at least one material having a high thermal conductivity for cooling one or more electronic components on a high density integrated circuit chip.

10. The computer system of claim 9 wherein at least one heatsink material is comprised of a metal selected from the group consisting of copper, aluminum or materials of similar thermal conductivity and mechanical flexibility.

11. A method of using a flexible radiating heatsink for cooling at least one electronic component on an integrated circuit chip that includes the steps of fabricating and installing at least one heatsink, comprised of one or more thermally conductive materials configured in an array of connected flexible joints that elastically deform without breaking or disconnecting from the chip in response to an external contact force and then return to an original size, shape and position without transmitting the external force to the cooled component(s),
wherein the array of flexible joints is comprised of a plurality of corrugated thin metal sheets joined together into a foldable skeletal construction having a limited area in contact with the cooled component(s) and an extended dimension providing at least one surface area exposed to ambient air for heat dissipation.

12. The method of claim 11 wherein the array assumes a configuration having sufficient flexibility to remain within plastic limits during deformation so as to resiliently absorb stress.

13. (canceled)

14. The method of claim 11 including the steps of fabricating and installing one or more heatsinks comprised of at least one material having a high thermal conductivity for cooling one or more electronic components on a high density integrated circuit chip.

15. The method of claim 14 wherein at least one heatsink material is comprised of a metal selected from the group consisting of copper, aluminum or materials of similar thermal conductivity and mechanical flexibility.

16. A flexible radiating heatsink of claim 1 wherein the array of flexible joints is formed without use of notched protrusions.

17. The computer system of claim 6 wherein the array of flexible joints is formed without use of notched protrusions.

18. The method of claim 11 wherein the array of flexible joints is formed without use of notched protrusions.
